(19) United States
(12) Patent Application Publication
(10) Pub. No.: US 2024/0113053 A1
(43) Pub. Date: Apr. 4, 2024

(54) SEMICONDUCTOR DEVICE AND METHOD OF PRODUCING THEREOF

(71) Applicant: Infineon Technologies AG, Neubiberg (DE)

(72) Inventors: Andreas Korzenietz, Putzbrunn (DE); Anton Mauder, Kolbermoor (DE); Christoffer Erbert, St. Magdalen (AT); Julia Zischang, Villach (AT)

(21) Appl. No.: 18/466,929

(22) Filed: Sep. 14, 2023

(30) Foreign Application Priority Data
Sep. 30, 2022 (DE) 102022210413.7

(51) Int. Cl. H01L 23/00

(52) U.S. Cl. CPC H01L 24/05; H01L 24/03; H01L 2224/05078; H01L 2924/13055

(57) ABSTRACT

The application relates to a power semiconductor device, including: a semiconductor body having a front side coupled to a frontside metallization and a backside coupled to a backside metallization; and an active region with a plurality of transistor cells. The frontside metallization includes a first load terminal structure and a control terminal structure. At least one of the first layer and the second layer is laterally segmented, with a first segment being part of the first load terminal structure and a second segment being part of the control terminal structure.

### TECHNICAL FIELD

The present disclosure relates to embodiments of a power semiconductor device. In particular, this specification refers to aspects of a power semiconductor device having a frontside metallization comprising two metal layers.

### BACKGROUND

Many functions of modern devices in automotive, consumer and industrial applications, such as converting electrical energy and driving an electric motor or an electric machine, rely on power semiconductor devices. For example, Insulated Gate Bipolar Transistors (IGBTs), Metal Oxide Semiconductor Field Effect Transistors (MOSFETs) and diodes, to name a few, have been used for various applications including, but not limited to switches in power supplies and power converters.

A power semiconductor device usually comprises a semiconductor body with an active region configured to conduct a load current along a load current path between two load terminals. Both load terminal may be provided by a respective metallization. In case of a vertical power semiconductor device, the semiconductor body is usually sandwiched between both the terminals. For a controlled power semiconductor device, e.g. having a gate or control electrode, an additional terminal, e.g. a control or gate terminal, may be necessary. For each terminal a bond pad for a connection via bond wires may be provided as part of said metallization. The bond pad for the gate terminal, however, consumes more chip area of the semiconductor body than necessary for the function of the semiconductor device.

It is thus desirable to reduce the loss of active area within the active region by the bonding pad.

### SUMMARY

Aspects described herein relate to a specific novel design of a backside region of a power semiconductor device that may, for example, usage of chip area compared to conventional designs.

According to an embodiment, a power semiconductor device comprises a semiconductor body having a front side being coupled to a frontside metallization and a backside being coupled to a backside metallization, wherein the frontside metallization comprises a first load terminal structure and a control terminal structure, wherein the backside metallization comprises a second load terminal structure being coupled to the backside, and wherein the power semiconductor device is configured for conducting a load current between the first load terminal structure and the second load terminal structure. The power semiconductor device further comprises an active region with a plurality of transistor cells, the plurality of transistor cells comprising gate structures being configured for controlling the load current and in electrical connection to the control terminal structure, a plurality of source regions being coupled to the first load terminal structure, and a body region being coupled to the first load terminal structure, wherein the frontside metallization comprises a first layer and a second layer above the first layer, wherein at least one of the first layer and the second layer is laterally segmented, with a first segment being part of the first load terminal structure and a second segment being part of the control terminal structure.

According to an embodiment, a power semiconductor device comprises a semiconductor body having a frontside being coupled to a frontside metallization and a backside being coupled to a backside metallization, wherein the frontside metallization comprises a first load terminal structure and a control terminal structure, wherein the backside metallization comprises a second load terminal structure being coupled to the backside, and wherein the power semiconductor device is configured for conducting a load current between the first load terminal structure and the second load terminal structure. The power semiconductor device further comprises an active region with a plurality of transistor cells, the plurality of transistor cells comprising gate structures being configured for controlling the load current and in electrical connection to the control terminal structure, a plurality of source regions being coupled to the first load terminal structure, and a body region being coupled to the first load terminal structure. The frontside metallization comprises a first layer and a second layer above the first layer, both the first layer and the second layer being laterally segmented, respective segments being either connected to the first load terminal or the control terminal. The frontside metallization comprises gate runner area where both the first layer and the second layer are electrically connected to the control terminal, an overlap area where the first layer is electrically connected to the first load terminal and the second layer is electrically connected to the control terminal, and a load terminal area where both the first layer and the second layer are electrically connected to the first load terminal.

According to an embodiment, a method for manufacturing a power semiconductor device comprises the following steps: Providing a semiconductor body having a frontside and a backside forming an active region with a plurality of transistor cells, the plurality of transistor cells comprising control structures being configured for controlling a load current, a plurality of source regions, and body region; forming a backside metallization comprising a second load terminal structure being coupled to the backside; forming a frontside metallization coupled to the frontside, wherein the frontside metallization comprises a first load terminal structure in electrical connection to the plurality of source regions and the body region, and a control terminal structure in electrical connection to the control structures. Therein forming the frontside metallization comprises forming a first layer, forming a second layer above the first layer, and segmenting at least one of the first layer and the second layer laterally into a first segment and a second segment, the first segment being part of the first load terminal structure and the second segment being part of the control terminal structure.

According to an embodiment, a method for manufacturing a power semiconductor device comprises the following steps: Providing a semiconductor body having a frontside and a backside forming an active region with a plurality of transistor cells, the plurality of transistor cells comprising control structures being configured for controlling a load current, a plurality of source regions, and body region; forming a backside metallization comprising a second load terminal structure being coupled to the backside; forming a frontside metallization coupled to the frontside, wherein the frontside metallization comprises a first load terminal structure in electrical connection to the plurality of source regions and the body region, and a control terminal structure in electrical connection to the control structures. Therein forming the frontside metallization comprises forming a first layer, forming a second layer above the first layer, and segmenting each of the first layer and the second layer laterally into a first segment and a second segment, wherein in gate runner area where both the first layer and the second layer are electrically connected to the control terminal, in an overlap area the first layer is electrically connected to the first load terminal and the second layer is electrically connected to the control terminal, and in a load terminal area both the first layer and the second layer are electrically connected to the first load terminal.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1A illustrates a cross sectional view of an embodiment of a power semiconductor device comprising a metallization comprising a first layer and a second layer.

FIG. 1B illustrates a top view of the same embodiment of a power semiconductor device comprising a first layer.

FIGS. 2A to 2D illustrate another embodiment of a power semiconductor device comprising a metallization comprising a first layer and a second layer in a cross sectional view.

FIG. 3 illustrates an embodiment of a method for manufacturing a semiconductor device.

### DETAILED DESCRIPTION

The examples described herein provide a power semiconductor device (in the following description also mentioned as semiconductor device). The power semiconductor device comprises a semiconductor body with a first surface and a second surface. The power semiconductor device has an active region comprising at least one semiconductor cell for conducting a load current between the first surface and the second surface. The power semiconductor device comprises an edge termination region separating the active region from a chip edge. Furthermore, the power semiconductor device comprises a first layer which is described in detail below.

In this specification, the term “above” does mean that a layer is applied on the surface of these device structures or regions or via one or more other structures or layers. Thereby the thin film layer may be directly on the device structures or regions or may extend directly onto another layer or element. Intervening layers or elements may also be present. In contrast, when a layer or an element is referred to as being “directly on” or extending “directly onto” another layer or element, there are no intervening layers or elements present.

The semiconductor device, such as a high voltage semiconductor device (e.g. a semiconductor chip) may, for example, be configured as an IGBT (Insulated Gate Bipolar Transistor), a FET (Field Effect Transistor), in particular a MOSFET (Metal Oxide Semiconductor FET), a JFET (Junction Gate FET), a thyristor, specifically a GTO (Gate Turn-Off) thyristor, a BJT (Bipolar Junction Transistor), an HEMT (High Electron Mobility Transistor), or a diode. By way of example, a source electrode and a gate electrode of, e.g., a FET or MOSFET may be situated on the top side surface, while the drain electrode of the FET or MOSFET may be arranged on the bottom side surface.

The semiconductor body may comprise a semiconductor substrate, e.g. a processed wafer or a wafer with epitaxial layers comprising several device structures on or over a surface of the wafer. The semiconductor substrate may comprise or be of a semiconductor material such as, e.g., Si, SiC, SiGe, GaAs, GaN, AlGaN, InGaAs, InAlAs, etc. For instance, the semiconductor substrate may be a wafer or a chip comprising an active region. The active region may comprise at least one semiconductor cell for conducting a load current between the first load terminal and the second load terminal arranged on the first and second surfaces thereof, respectively. For instance, the first and second load terminals may be formed by a high voltage electrically conductive structure, which is, e.g., made of metal. All kinds of metal or metal alloy may be used for the load terminals, though in many cases the metal may comprise or be of aluminum or copper or an alloy of aluminum or copper. Examples of the load terminals are set out further below. It is to be noted that load terminals may be located relatively close to the anode of the active region so as to be subjected to high electrical fields during operation of the semiconductor device. The load terminals may be configured to be applied with a high voltage of equal to or greater than 0.6 kV, 1 kV, 2 kV, 3 kV or 4 kV or 5 kV or 6 kV or 6.5 kV during operation. This voltage may be applied between a first load terminal (e.g. anode, source, emitter or another electrically conductive structure connected with the first load terminal) and a second load terminal of the power semiconductor device (e.g. a cathode, drain or collector at the bottom side of the semiconductor body) arranged, e.g., at a surface of the semiconductor body opposite to the surface of the semiconductor body where the first load terminal is provided.

An edge termination region may be between the active region and a chip edge of the semiconductor body, e. g. near the first surface. For example, the edge termination region may be arranged within the semiconductor body in proximity to the first surface or adjoining the first surface. The chip edge may be a lateral border of the semiconductor body. The chip edge may be cutting edge resulting from separating the semiconductor body from a wafer during manufacture. The chip edge may indicate the border between the first surface and the second surface of the semiconductor body. In some examples, the chip edge may also define the boarder to a neighboring chip on a wafer substrate. Two or more such chips may be placed on a single wafer, and each may have chip edges related to its neighboring chips. The edge termination region, thus, helps to separate the chips integrated on one wafer. Moreover, the edge termination region can be used to facilitate the separation of the individual chips within the edge termination region when slicing the individual chips from a wafer with a number of chips during manufacturing of the semiconductor device.

According to an embodiment, a power semiconductor device comprises a semiconductor body having a front side being coupled to a frontside metallization and a backside being coupled to a backside metallization, wherein the frontside metallization comprises a first load terminal structure and a control terminal structure, wherein the backside metallization comprises a second load terminal structure being coupled to the backside, and wherein the power semiconductor device is configured for conducting a load current between the first load terminal structure and the second load terminal structure. The power semiconductor device further comprises an active region with a plurality of transistor cells, the plurality of transistor cells comprising gate structures being configured for controlling the load current and in electrical connection to the control terminal structure, a plurality of source regions being coupled to the first load terminal structure, and a body region being coupled to the first load terminal structure, wherein the frontside metallization comprises a first layer and a second layer above the first layer, wherein at least one of the first layer and the second layer is laterally segmented, with a first segment being part of the first load terminal structure and a second segment being part of the control terminal structure.

According to an embodiment, a power semiconductor device comprises a semiconductor body having a frontside being coupled to a frontside metallization and a backside being coupled to a backside metallization, wherein the frontside metallization comprises a first load terminal structure and a control terminal structure, wherein the backside metallization comprises a second load terminal structure being coupled to the backside, and wherein the power semiconductor device is configured for conducting a load current between the first load terminal structure and the second load terminal structure. The power semiconductor device further comprises an active region with a plurality of transistor cells, the plurality of transistor cells comprising gate structures being configured for controlling the load current and in electrical connection to the control terminal structure, a plurality of source regions being coupled to the first load terminal structure, and a body region being coupled to the first load terminal structure. The frontside metallization comprises a first layer and a second layer above the first layer, both the first layer and the second layer being laterally segmented, respective segments being either connected to the first load terminal or the control terminal. The frontside metallization comprises gate runner area where both the first layer and the second layer are electrically connected to the control terminal, an overlap area where the first layer is electrically connected to the first load terminal and the second layer is electrically connected to the control terminal, and a load terminal area where both the first layer and the second layer are electrically connected to the first load terminal.

According to an embodiment, a method for manufacturing a power semiconductor device comprises the following steps: Providing a semiconductor body having a frontside and a backside forming an active region with a plurality of transistor cells, the plurality of transistor cells comprising control structures being configured for controlling a load current, a plurality of source regions, and body region; forming a backside metallization comprising a second load terminal structure being coupled to the backside; forming a frontside metallization coupled to the frontside, wherein the frontside metallization comprises a first load terminal structure in electrical connection to the plurality of source regions and the body region, and a control terminal structure in electrical connection to the control structures. Therein forming the frontside metallization comprises forming a first layer, forming a second layer above the first layer, and segmenting at least one of the first layer and the second layer laterally into a first segment and a second segment, the first segment being part of the first load terminal structure and the second segment being part of the control terminal structure.

According to an embodiment, a method for manufacturing a power semiconductor device comprises the following steps: Providing a semiconductor body having a frontside and a backside forming an active region with a plurality of transistor cells, the plurality of transistor cells comprising control structures being configured for controlling a load current, a plurality of source regions, and body region; forming a backside metallization comprising a second load terminal structure being coupled to the backside; forming a frontside metallization coupled to the frontside, wherein the frontside metallization comprises a first load terminal structure in electrical connection to the plurality of source regions and the body region, and a control terminal structure in electrical connection to the control structures. Therein forming the frontside metallization comprises forming a first layer, forming a second layer above the first layer, and segmenting each of the first layer and the second layer laterally into a first segment and a second segment, wherein in gate runner area where both the first layer and the second layer are electrically connected to the control terminal, in an overlap area the first layer is electrically connected to the first load terminal and the second layer is electrically connected to the control terminal, and in a load terminal area both the first layer and the second layer are electrically connected to the first load terminal.

In the following some further examples are provided, that apply to all embodiments of the present application.

For example, the second segment of the first layer may form a gate runner. The second segment of the first layer may at least partly encompass the active region. For example, the second segment of the second layer may form a bond pad.

For example, both the first layer and the second layer are laterally segmented, the first layer comprising a first segment being part of the first load terminal structure and a second segment being part of the control terminal structure and the second layer comprising a first segment being part of the first load terminal structure and a second segment being part of the control terminal structure. In other words, both the first layer and the second layer may comprise separate segments which are electrically separated from each other allowing them to have a different potential. Both layers may have the potential of the control terminal structure and the first load terminal structure in different segments each. For example, second segments of both the first and the second layer may be electrically connected to the control terminal (and also be part of the control terminal). For example, first segments of both the first and the second layer may be electrically connected to the first load terminal (and also be part of the first load terminal). In a load terminal area both the first and the second layer may be electrically connected to the first load terminal.

For example, in an overlap area, the second segment of the second layer laterally overlaps the first segment of the first layer. In the overlap area, the second segment of the second layer may be electrically connected to the control terminal structure and the first segment of the first layer may be electrically connected to the first load terminal structure.

For example, the second segment of the second layer is laterally surrounded by the first segment of the second layer on at least two opposing faces. For example, the second segment of the second layer is arranged laterally between two portions of the first segment of the second layer, particularly on the at least two opposing faces. The second segment of the second layer may laterally divide the second segment of the second layer into these two portions. In this case, the second segment of the second layer may be configured as gate finger extending through the active region, e.g. from center of the chip at least partly towards the chip edge.

For example, the second segment of the second layer is laterally neighboring the first segment of the second layer on at least two neighboring faces. For example, the second segment of the second layer is arranged in an edge of the active region or outside the active region. In this case, the second segment of the second layer may be configured as bond pad.

For example, the second segment of the first layer is laterally surrounded by the first segment of the first layer on at least two opposing faces. For example, the second segment of the first layer is arranged laterally between two portions of the first segment of the first layer, particularly on the at least two opposing faces. The second segment of the first layer may laterally divide the second segment of the first layer into these two portions. In this case, the second segment of the first layer may be configured as gate finger extending through the active region, e.g. from center of the chip at least partly towards the chip edge.

For example, in a lateral cross-section, the second segment of the first layer has a smaller lateral extension than the second segment of the second layer. For example, the second segment of the second layer may protrude over the second segment of the first layer. This may provide an increased area (in a top view on the chip) of the second segment of the second layer compared to the second segment of the first layer. The greater area may provide a bonding pad. On the other hand, by minimizing the lateral extension of the second segment of the first layer, the loss of active area may be reduced.

For example, the frontside metallization comprises a dielectric structure between the first and the second layer at least in the overlap area, the first and the second layer being electrically insulated by the dielectric structure in the overlap area. The dielectric structure or, respectively, a dielectric layer may be arranged between the first and the second layer at least in the overlap area. The dielectric layer or, respectively, the insulating portion may be configured to insulate the different potentials of the first layer and the second layer in the overlap area. The dielectric structure may comprise the dielectric layer, e.g. an oxide layer. The dielectric structure may comprise a silicon oxide layer, e.g. a deposited silicon oxide layer or a deposited silicon nitride layer or a deposited silicon oxynitride layer or a layer stack comprising one or more of the aforementioned layers.

For example, the dielectric structure is further arranged between the first segment of the first layer and the first segment of the second layer, wherein first segment of the first layer and the first segment of the second layer are electrically connected through openings of the dielectric structure. For example, the dielectric structure also extends between the first segment of the first layer and the first segment of the second layer, wherein first segment of the first layer and the first segment of the second layer are electrically connected through openings of the dielectric structure. For example, the dielectric structure also extends into the load terminal area. For example, the dielectric structure is a least partly grid-shaped between the first segment of the first layer and the first segment of the second layer. The first and second layer may than be interconnected through openings in the grid. The dielectric structure may comprise the same material in both, the overlap area and the load terminal area.

For example, the first layer and the second layer comprise a different metal. For example, the first layer and the second layer comprise a same metal. For example, the second layer has a greater thickness than the first layer. By varying the material and/or thickness, the second layer may be optimized for bonding independently from the first layer.

For example, the second segment of the second layer is arranged close to a chip edge of the semiconductor body than every first segment of the second layer. For example, the second segment of the second layer is arranged with greater lateral distance to a center of the semiconductor body than every first segment of the second layer. For example, the second segment of the second layer may be arranged in a corner of the semiconductor body.

For example, the second layer in the overlap area forms a bond pad of the control terminal.

For example, a plurality of transistor cells may be arranged in the active region. For example, some of the plurality of transistor cells are arranged below the second segment of the second layer or, respectively, in the overlap area.

For example, the power semiconductor device may be configured as a RC-IGBT wherein a diode anode structure is arranged below the second segment of the second layer or, respectively, in the overlap area. Arranging diode cells in the overlap area may be advantageous, as no trenches are required even if the IGBT cells are based on trench technology.

In the following, reference is made to the accompanying drawings which form a part hereof and in which are shown by way of illustration specific embodiments in which the invention may be practiced.

In this regard, directional terminology, such as “top”, “bottom”, “below”, “front”, “behind”, “back”, “leading”, “trailing”, “above” etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a horizontal surface of a semiconductor substrate or of a semiconductor structure. This can be for instance the surface of a semiconductor wafer or a die or a chip. For example, both the first lateral direction X and the second lateral direction Y mentioned below can be horizontal directions, wherein the first lateral direction X and the second lateral direction Y may be perpendicular to each other.

The term “vertical” as used in this specification intends to describe an orientation which is substantially arranged perpendicular to the horizontal surface, i.e., parallel to the normal direction of the surface of the semiconductor wafer/chip/die. For example, the extension direction Z mentioned below may be an extension direction that is perpendicular to both the first lateral direction X and the second lateral direction Y. The extension direction Z is also referred to as “vertical direction Z” herein.

In this specification, n-doped is referred to as “first conductivity type” while p-doped is referred to as “second conductivity type”. Alternatively, opposite doping relations can be employed so that the first conductivity type can be p-doped and the second conductivity type can be n-doped.

In the context of the present specification, the terms “in ohmic contact”, “in electric contact”, “in ohmic connection”, and “electrically connected” intend to describe that there is a low ohmic electric connection or low ohmic current path between two regions, sections, zones, portions or parts of a semiconductor device or between different terminals of one or more devices or between a terminal or a metallization or an electrode and a portion or part of a semiconductor device, wherein “low ohmic” may mean that the characteristics of the respective contact are essentially not influenced by the ohmic resistance. Further, in the context of the present specification, the term “in contact” intends to describe that there is a direct physical connection between two elements of the respective semiconductor device; e.g., a transition between two elements being in contact with each other may not include a further intermediate element or the like.

In addition, in the context of the present specification, the term “electric insulation” is used, if not stated otherwise, in the context of its general valid understanding and thus intends to describe that two or more components are positioned separately from each other and that there is no ohmic connection connecting those components. However, components being electrically insulated from each other may nevertheless be coupled to each other, for example mechanically coupled and/or capacitively coupled and/or inductively coupled. To give an example, two electrodes of a capacitor may be electrically insulated from each other and, at the same time, mechanically and capacitively coupled to each other, e.g., by means of an insulation, e.g., a dielectric.

Specific embodiments described in this specification pertain to, without being limited thereto, a power semiconductor device, e.g., a power semiconductor device that may be used within a power converter or a power supply. Thus, in an embodiment, such device can be configured to carry a load current that is to be fed to a load and/or, respectively, that is provided by a power source. For example, the power semiconductor device may comprise one or more active power semiconductor unit cells, such as a monolithically integrated diode cell, a derivative of a monolithically integrated diode cell (e.g., a monolithically integrated cell of two anti-serially connected diodes), a monolithically integrated transistor cell, e.g., a monolithically integrated MOSFET or IGBT cell and/or derivatives thereof. Such diode/transistor cells may be integrated in a power semiconductor module. A plurality of such cells may constitute a cell field that is arranged within the active region of the power semiconductor device.

The term “power semiconductor device” as used in this specification intends to describe a semiconductor device on a single chip with high voltage blocking and/or high current-carrying capabilities. In other words, such power semiconductor device is intended for high current, typically in the Ampere range, e.g., up to several ten or hundred Ampere, and/or high voltages, typically above 15 V, more typically 100 V and above, e.g., up to at least 400 V or even more, e.g., up to at least 3 kV, or even up to 10 kV or more, depending on the respective application.

For example, the term “power semiconductor device” as used in this specification is not directed to logic semiconductor devices that are used for, e.g., storing data, computing data and/or other types of semiconductor based data processing.

The present specification in particular relates to a power semiconductor device embodied as a diode, a MOSFET or IGBT, i.e., a unipolar or bipolar power semiconductor transistor or diode or a derivate thereof.

For example, the power semiconductor device described below may be a single semiconductor chip, e.g., exhibiting a stripe cell configuration (or a cellular/needle cell configuration) and can be configured to be employed as a power component in a low-, medium- and/or high voltage application. However, the herein proposed technical teaching may also be applied to a power semiconductor device having a cellular/needle cell configuration.

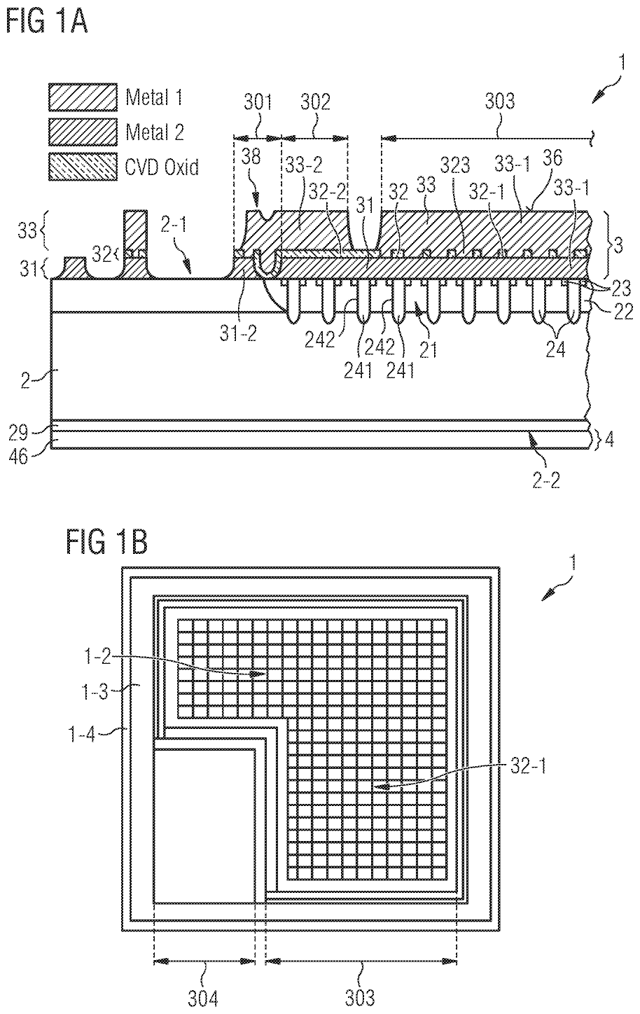

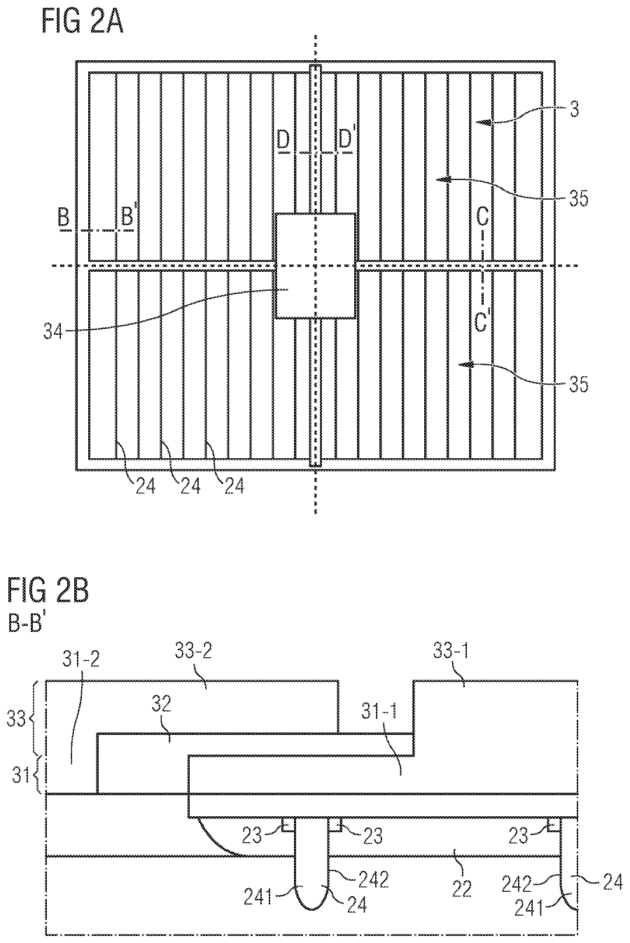

FIG. 1B illustrates a section of a horizontal projection of a power semiconductor device 1 in accordance with one or more embodiments. The power semiconductor device 1 exhibits, for example, an IGBT-configuration or a diode-configuration or an RC-IGBT-configuration. The power semiconductor device 1 comprises a semiconductor body 10 coupled to a frontside metallization 3 and a backside metallization 4. An active region 1-2 is configured to conduct a load current between a frontside 2-1 and a backside 2-2 of the semiconductor body 10. The semiconductor body 10 may comprise a drift zone 2 of a first conductivity type.

As illustrated, e.g. in FIG. 1A, the semiconductor body 10 may be sandwiched between the frontside metallization 3 and the backside metallization 4. Hence, the power semiconductor device 1 may exhibit a vertical configuration, according to which the load current follows a path substantially in parallel to the vertical direction Z. The active region 1-2 may be confined by a border where the active region 1-2 transitions into the edge termination region 1-3, which is in turn terminated by the chip edge 1-4. Within the edge termination region 1-3 the power semiconductor device 1 may comprise an edge termination structure. The edge termination structure may be arranged at least partly within the semiconductor body 10, e.g. adjacent to a first surface or the frontside 2-1 of the power semiconductor device 1. Next to the second surface 2-2, the semiconductor body 10 may comprise a highly doped semiconductor region 29, e.g. to provide an ohmic connection to the backside metallization 4. The semiconductor region 29 may comprise the first conductivity type or the second conductivity type or portions of each conductivity type.

Herein, the terms active region and edge termination region are used in a technical context the skilled person typically associates with these terms. Accordingly, the purpose of the active region 1-2 is primarily to ensure load current conduction, whereas the edge termination region 1-3 is configured to reliably terminate the active region 1-2, e.g. in terms of courses of the electric field during conduction state and during blocking state.

The frontside metallization 3 comprises a first load terminal structure 36 and a control terminal structure 38. The backside metallization comprises a second load terminal structure 46 being coupled to the backside 2-2. The power semiconductor device 1 is configured for conducting the load current between the first load terminal structure 36 and the second load terminal structure 46.

For controlling the load current, the power semiconductor device 1 may comprise one or more semiconductor cells, e.g. IGBT cells, diode cells, MOSFET cell, or the like. Also a combination of different types of semiconductor cells is possible, e.g. a combination of IGBT cells and diode cells in case of a RC-IGBT (reverse conducting IGBT). According to the embodiment of FIG. 1A, IGBT cells 21 are shown. IGBT cells 21, for example, comprise a body region 22 and source regions 23. The source regions 23 are arranged next to a control electrode 24. The control electrode 24 may be coupled to the control terminal structure 38. The control electrode 24 may be arranged within a trench extending form the frontside 2-1 into the semiconductor body (along the vertical direction Z). In other examples, the control electrode 24 may be planar. The control electrode 24 is electrically insulated from the semiconductor body by a gate dielectric 242. The source regions 23 and the body region 22 are electrically connected to the first load terminal structure 36. Adjoining the backside 2-2, the semiconductor body 10 may comprise at least backside semiconductor region, e.g. for providing an ohmic contact to the second load terminal 46. As shown in FIG. 1A, not all trenches may be connected to the control electrode 24 but also be connected to another electrode like e. g. to the source electrode or first load terminal structure 36. Further, not all trenches connected to the control electrode 24 may be neighbored by source regions 23.

The frontside metallization 3 comprises a first layer 31 and a second layer 33. Furthermore, the frontside metallization 3 comprises a dielectric structure 32. The first layer 31 and the second layer 33 are laterally segmented. The first layer 31 comprises a first segment 31-1 being part of the first load terminal structure 36 and a second segment 31-2 being part of the control terminal structure 38. The second layer 33 comprises a first segment 33-1 being part of the first load terminal structure 36 and a second segment 33-2 being part of the control terminal structure 38.

In a load terminal area 303, first segments 31-1, 33-1 of both the first 31 and the second layer 33 are electrically connected to the first load terminal 36 (and also be part of the first load terminal 36). In an overlap area 302, the second segment 33-2 of the second layer 33 laterally overlaps the first segment 31-1 of the first layer 31. In the overlap area 302, the second segment 33-2 of the second layer 33 is electrically connected to the control terminal structure 38 and the first segment 31-1 of the first layer 31 is electrically connected to the first load terminal structure 36. In a gate runner area 301, second segments 31-2, 33-2 of both the first 31 and the second layer 33 are electrically connected to the control terminal 38 (and also be part of the control terminal 38). FIG. 1B shows a bond pad area 304 of the bond pad of the control terminal structure 38. The bond pad area 304 may correspond to the gate runner area 301 and the overlap area 302 combined.

In the lateral cross-section of FIG. 1A, the second segment 31-2 of the first layer 31 has a smaller lateral extension than the second segment 33-2 of the second layer 33. The second segment 31-2 of the second layer 33 therefore protrudes laterally over the second segment 31-2 of the first layer 31 thus increasing the area suitable for bonding. The second layer 33 has a greater thickness than the first layer 31. By varying the material and/or thickness, the second layer 33 may be optimized for bonding independently from the first layer 31.

For example, the second segment 31-2 of the first layer 31 may form a gate runner. The second segment 31-2 of the first layer 31 may at least partly encompass the active region (c.f. FIG. 1B). For example, the second segment 33-2 of the second layer 33 forms a bond pad of the gate terminal structure 38.

The first segment 31-1 of the first layer 31 connects the semiconductor cells, e.g. the source regions 23 and the body region 22. The first segment 31-1 of the first layer 31 may therefore be referred to as wiring layer. For example, the first segment 33-1 of the second layer 33 forms a bond pad of the first load terminal structure 36.

The dielectric structure 32 comprises a dielectric layer 32-2 between the first layer 31 and the second layer 33 at least in the overlap area 302. The first 31 and the second layer 33 are electrically insulated by the dielectric structure 32 or, respectively, the dielectric layer 32-2 in the overlap area 302. The dielectric structure or, respectively, the dielectric layer 32-2 may be arranged between the first 31 and the second layer 33 at least in the overlap area 302.

For example, the dielectric structure 32 is further arranged between the first segment 31-1 of the first layer 31 and the first segment 33-1 of the second layer 33. Within the load terminal area 303, the first layer 31 and second layer 32 are electrically connected through openings 323 of the dielectric structure 32. As depicted in FIG. 1B, the dielectric structure may be at least partly grid-shaped within the load terminal area 303.

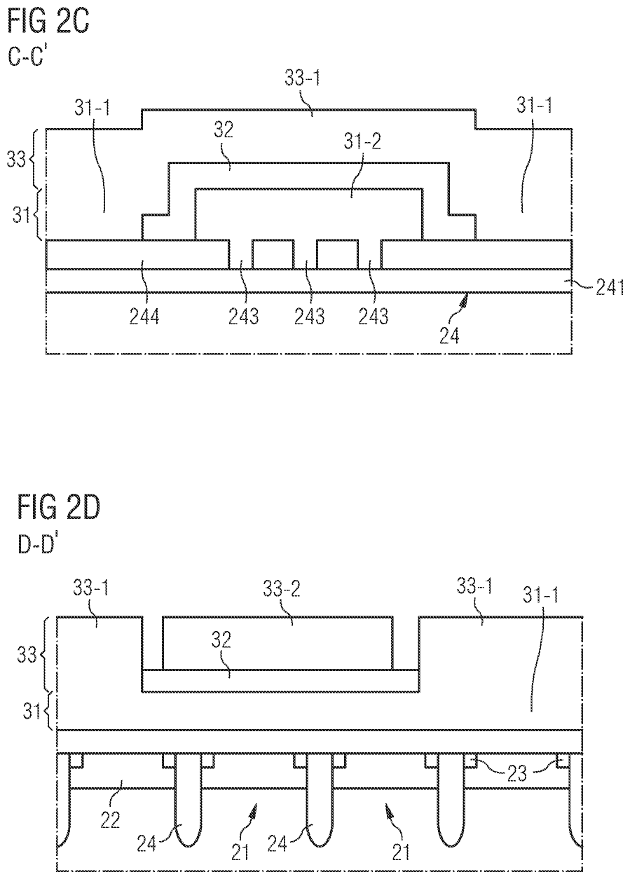

FIG. 2A shows another vertical projection of an embodiment of a power semiconductor device 1. Therein, the gate pad G is arranged in a center of the chip. According to the embodiments of FIGS. 2C (section C-C′ of FIG. 2A) and to 2D (section D-D′ of FIG. 2A), different embodiments of a gate finger crossing the active region 1-2 are shown. gate finger extending through the active region, e.g. from a center of the chip. The gate finger extends from the center towards the chip edge 1-4 through the active region 1-2. In each embodiment, the gate finger is provided in only one of the two layers 31, 33. FIG. 2B (section B-B′ of FIG. 2A) corresponds to the embodiments of FIGS. 1A and 1B. In the example, all the embodiments of FIGS. 2B, 2C and 2D correspond to the example of FIG. 2A. However, it is obvious, that features of FIGS. 2B, 2C and 2D are also covered on their own.

According to the embodiments of FIG. 2C, the gate finger is formed in the second segment 31-2 of the first layer 31. At least the second segment 31-2 of the first layer 31 is electrically insulated from the semiconductor body 10 by a dielectric layer 244. The control electrodes 24 may be connected to the second segment 31-2 of the first layer 31 through openings 243. FIG. 2C is a section along a control electrode 24. The second segment 31-2 of the first layer 31 connects the control electrodes 24 to the control terminal structure 38. The second segment 31-2 of the first layer 31 is laterally surrounded by the first segments 31-1 of the first layer 31 on at least two opposing faces. In total, the second segment 31-2 of the first layer 31 is laterally surrounded by portions (the first segments 31-1 of the first layer 31 and the first segment 33-1 of the second layer 33) of the first load terminal 36 on three sides, particularly on the two opposing faces as well as from above.

According to the embodiments of FIG. 2D, the gate finger is formed in the second segment 33-2 of the second layer 33. The second segment 33-2 of the second layer 33 is electrically insulated from the first layer 31 (or more particularly, the first segment 31-1 of the first layer 31) by a dielectric structure 32, e.g. an oxide layer. The second segment 33-2 of the second layer 33 is laterally surrounded by the first segments 33-1 of the second layer 33 on at least two opposing faces. In total, the second segment 33-2 of the second layer 33 is laterally surrounded by portions (the first segments 33-1 of the second layer 33 and the first segment 31-1 of the first layer 31) of the first load terminal 36 on three sides, particularly on the two opposing faces as well as from below.

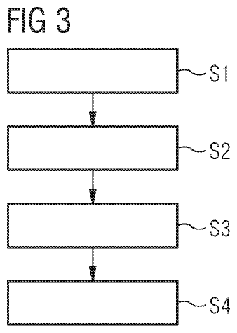

FIG. 3 represent a method for manufacturing a power semiconductor device (1), comprising the following steps:
S1: Providing a semiconductor body 2 having a frontside 2-1 and a backside 2-2;
S2: Forming an active region with a plurality of transistor cells 21, the plurality of transistor cells 21 comprising control structures 24 being configured for controlling a load current, a plurality of source regions 23, and a body region 22.
S3: Forming a backside metallization 4 comprising a second load terminal structure 46 being coupled to the backside 2-2;
S4: Forming a frontside metallization 3 coupled to the frontside 2-1, wherein the frontside metallization 3 comprises a first load terminal structure 36 in electrical connection to the plurality of source regions 23 and the body region 22 and a control terminal structure 38 in electrical connection to the control structures 24; wherein forming the frontside metallization 3 comprises forming a first layer 31, forming a second layer 33 above the first layer 31, and segmenting at least one of the first layer 31 and the second layer 33 laterally into a first segment 31-1, 33-1 and a second segment 31-2, 33-2, the first segment 31-1, 33-1 being part of the first load terminal structure 36 and the second segment 31-2, 33-2 being part of the control terminal structure 38.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A power semiconductor device, comprising:
a semiconductor body having a front side coupled to a frontside metallization and a backside coupled to a backside metallization, wherein:
the frontside metallization comprises a first load terminal structure and a control terminal structure,
the backside metallization comprises a second load terminal structure coupled to the backside; and
the power semiconductor device is configured to conduct a load current between the first load terminal structure and the second load terminal structure;
an active region with a plurality of transistor cells, the plurality of transistor cells comprising:
gate structures configured to control the load current and in electrical connection to the control terminal structure;
a plurality of source regions coupled to the first load terminal structure; and
a body region coupled to the first load terminal structure,
wherein the frontside metallization comprises a first layer and a second layer above the first layer,
wherein at least one of the first layer and the second layer is laterally segmented, with a first segment being part of the first load terminal structure and a second segment being part of the control terminal structure.

2. The power semiconductor device of claim 1, wherein both the first layer and the second layer are laterally segmented, wherein the first layer comprises a first segment that is part of the first load terminal structure and a second segment that is part of the control terminal structure, and wherein the second layer comprises a first segment that is part of the first load terminal structure and a second segment that is part of the control terminal structure.

3. The power semiconductor device of claim 2, wherein in an overlap area, the second segment of the second layer laterally overlaps the first segment of the first layer.

4. The power semiconductor device of claim 2, wherein the second segment of the second layer is laterally surrounded by the first segment of the second layer on at least two opposing faces.

5. The power semiconductor device of claim 2, wherein the second segment of the first layer is laterally surrounded by the first segment of the first layer on at least two opposing faces.

6. A power semiconductor device, comprising:
a semiconductor body having a frontside coupled to a frontside metallization and a backside coupled to a backside metallization, wherein:
the frontside metallization comprises a first load terminal structure and a control terminal structure;
the backside metallization comprises a second load terminal structure coupled to the backside; and
the power semiconductor device is configured to conduct a load current between the first load terminal structure and the second load terminal structure;
an active region with a plurality of transistor cells, the plurality of transistor cells comprising:
gate structures configured to control the load current and in electrical connection to the control terminal structure;
a plurality of source regions coupled to the first load terminal structure; and
a body region coupled to the first load terminal structure,
wherein the frontside metallization comprises a first layer and a second layer above the first layer, both the first layer and the second layer being laterally segmented, respective segments being either connected to the first load terminal or the control terminal structure,
wherein the frontside metallization comprises:
a gate runner area where both the first layer and the second layer are electrically connected to the control terminal structure;
an overlap area where the first layer is electrically connected to the first load terminal and the second layer is electrically connected to the control terminal structure; and
a load terminal area where both the first layer and the second layer are electrically connected to the first load terminal.

7. The power semiconductor device of claim 6, wherein in a lateral cross-section, a second segment of the first layer has a smaller lateral extension than a second segment of the second layer.

8. The power semiconductor device of claim 6, wherein the frontside metallization comprises a dielectric structure between the first layer and the second layer at least in the overlap area, and wherein the first layer and the second layer are electrically insulated by the dielectric structure in the overlap area.

9. The power semiconductor device of claim 8, wherein the dielectric structure extends between a first segment of the first layer and a first segment of the second layer, and wherein first segment of the first layer and the first segment of the second layer are electrically connected through openings of the dielectric structure.

10. The power semiconductor device of claim 9, wherein the dielectric structure is a least partly grid-shaped between the first segment of the first layer and the first segment of the second layer.

11. The power semiconductor device of claim 6, wherein the first layer and the second layer comprise a different metal.

12. The power semiconductor device of claim 6, wherein the first layer and the second layer comprise a same metal.

13. The power semiconductor device of claim 6, wherein a second segment of the second layer is arranged closer to a chip edge of the semiconductor body than every first segment of the second layer.

14. The power semiconductor device of claim 6, wherein the second layer in the overlap area forms a bond pad of the control terminal structure.

15. The power semiconductor device of claim 6, wherein some of the plurality of transistor cells are arranged below a second segment of the second layer or, respectively, in the overlap area.

16. The power semiconductor device of claim 6, wherein the power semiconductor device is configured as a RC-IGBT, and wherein a diode anode structure is arranged below a second segment of the second layer or, respectively, in the overlap area.

17. A method for manufacturing a power semiconductor device, the method comprising:
providing a semiconductor body having a frontside and a backside;
forming an active region with a plurality of transistor cells, the plurality of transistor cells comprising control structures configured to control a load current, a plurality of source regions, and a body region;
forming a backside metallization comprising a second load terminal structure coupled to the backside;
forming a frontside metallization coupled to the frontside, the frontside metallization comprising a first load terminal structure in electrical connection to the plurality of source regions and the body region, and a control terminal structure in electrical connection to the control structures,
wherein forming the frontside metallization comprises:
forming a first layer;
forming a second layer above the first layer; and
segmenting at least one of the first layer and the second layer laterally into a first segment and a second segment, the first segment being part of the first load terminal structure and the second segment being part of the control terminal structure.

18. The method of claim 17, wherein at least one of the first layer and the second layer is formed as contiguous layer prior to the segmenting.

19. The method of claim 17, wherein forming the frontside metallization further comprises:
forming a dielectric structure above the first layer; and
segmenting the dielectric structure,
wherein the second layer is formed above the dielectric structure after segmenting the dielectric structure.

20. The method of claim 19, wherein segmenting the dielectric structure comprises forming an insulating portion that insulates the first layer from the second layer, and a connecting portion that comprises openings through which the first layer and the second layer are electrically connected.
